(19) United States
(12) Patent Application Publication
(10) Pub. No.: US 2009/0053852 A1
(43) Pub. Date: Feb. 26, 2009

(54) MANUFACTURING APPARATUS AND METHOD FOR AN ELECTRONIC APPARATUS

(75) Inventors: Shuichi Takeuchi, Kawasaki (JP); Kenji Kobae, Kawasaki (JP); Takashi Kubota, Kawasaki (JP); Hiroshi Kobayashi, Kawasaki (JP)

Correspondence Address: STAAS & HALSEY LLP, SUITE 700, 1201 NEW YORK AVENUE, N.W., WASHINGTON, DC, 20005, US

(73) Assignee: Fujitsu Limited, Kanagawa (JP)

(21) Appl. No.: 12/192,225

(22) Filed: Aug. 15, 2008

(30) Foreign Application Priority Data
Aug. 20, 2007 (JP) 2007-213218

(51) Int. Cl. H05K 3/30; H05K 13/04

(52) U.S. Cl. 438/106; 29/832; 29/729; 361/782; 361/764; 438/122

(57) ABSTRACT

A manufacturing method for an electronic apparatus and manufacturing apparatus are provided. The manufacturing method includes applying to a surface of a sheet an adhesive to be charged into a space between a mounting board and an electronic component mounted on the mounting board, bringing the one surface of the sheet into contact with a back surface of the electronic component mounted on the mounting board and charging the adhesive into the space by bringing the adhesive into contact with a peripheral portion of the electronic component under a low pressure, and pressing a heating head against the other surface of the sheet and heating the sheet with the heating head via the sheet to set the adhesive under atmospheric pressure, in a state that the sheet is in contact with the electronic component.

### CROSS-REFERENCE TO RELATED APPLICATION

This application is related to and claims priority to Japanese Patent Application No. 2007-213218 filed on Aug. 20, 2007, and incorporated herein by reference.

### BACKGROUND

1. Field

The embodiments discussed herein are directed to charging an adhesive between a mounting board and an electronic component that is mounted on the mounting board and an electronic apparatus manufacturing method and apparatus.

2. Description of the Related Art

Electronic apparatuses, such as a semiconductor device, may have a space between a mounting board and an electronic component mounted on the mounting board filled with an adhesive. An example is a semiconductor device in which a semiconductor chip is flip-chip-connected to a mounting wiring board.

A conventional method for filling the space of such an electronic apparatus with an adhesive is illustrated in FIG. 1 in which an adhesive 105 is supplied to a neighborhood of a space 104 between a mounting board 102 and an electronic component 103 from a needle 112 while the mounting board 102 is heated on a hot plate 111, whereby the space 104 is filled with the adhesive 105 by the capillary phenomenon.

However, electronic apparatuses in which a space is filled with an adhesive by such a conventional method may have a problem in that their reliability decreases due to, for example, a reduction of adhesion that may be caused by formation of uncharged portions in the adhesive. For example, if a void (e.g., an air bubble formed in the adhesive at the time of charging) exists between stud bumps or interconnections, problems may occur such as short-circuiting to an adjacent interconnection due to migration. Therefore, as a wiring pitch used decreases, the importance increases in taking appropriate measures regarding voids between interconnections.

A conventional manufacturing method for an electronic apparatus capable of suppressing formation of voids in charging an adhesive is illustrated in FIG. 2. This manufacturing method has an operation of joining plural electrodes 224 that are formed two-dimensionally on one major surface 222 of a semiconductor chip 220 to corresponding conductive regions 232 and 234 on a board 230, an operation of supplying an adhesive 240 which is an underfill resin between the one major surface 222 of the semiconductor chip 220 and the board 230 in vacuum, and an operation of exposing, to the air, the semiconductor chip 220 and the board 230 which have been supplied with the adhesive 240. This manufacturing method may suppress some formation of voids in an adhesive and may increase reliability in manufacture of a semiconductor device with reliable flip-chip mounting.

On the other hand, as illustrated in FIG. 3, many electronic apparatuses include a semiconductor chip 303 that is flip-chip-connected to a mounting board 302 and memory chips 306a and 306b, for example, are stacked on the semiconductor chip 303. In such electronic apparatuses, it is important to take to prevent formation of voids in an adhesive 305 in charging the adhesive 305 into a space 304 between the mounting board 302 and the semiconductor chip 303. It is also important to prevent problems occurring when parts 305a and 305b of the adhesive 305 may stick to the back surface 303a of the semiconductor chip 303 on which the memory chips etc. are to be stacked and make the stacking difficult to perform. Furthermore, it is important to prevent problems, as illustrated FIG. 4, where the adhesive 305 may have bulges 305c and 305d higher than the back surface 303a of the semiconductor chip 303 around the back surface 303a. This may result in a heating head 308, used in heating the adhesive 305 to set, not being able to be brought into contact with the back surface 303a.

### SUMMARY

It is an aspect of the embodiments discussed herein to provide a manufacturing method for an electronic apparatus including applying to a surface of a sheet an adhesive to be charged into a space between a mounting board and an electronic component mounted on the mounting board. The apparatus may include bringing one surface of the sheet into contact with a back surface of the electronic component mounted on the mounting board and charging the adhesive into the space by bringing the adhesive into contact with a peripheral portion of the electronic component under a low pressure, and pressing a heating head against the other surface of the sheet and heating the sheet with the heating head via the sheet to set the adhesive under atmospheric pressure, in a state that the sheet is in contact with the electronic component.

These together with other aspects and advantages which will be subsequently apparent, reside in the details of construction and operation as more fully hereinafter described and claimed, reference being had to the accompanying drawings forming a part hereof wherein like numerals refer to like parts throughout.

### BRIEF DESCRIPTION OF THE DRAWINGS

FIG. 1 illustrates a conventional manufacturing method for an electronic apparatus;

FIG. 2 illustrates another conventional manufacturing method for an electronic apparatus;

FIG. 3 illustrates a problem of a conventional manufacturing method for an electronic apparatus;

FIG. 4 illustrates another problem of a conventional manufacturing method;

FIG. 5 illustrates an embodiment of a manufacturing method for an electronic apparatus;

FIGS. 6A and 6B illustrate an example of a sheet;

FIG. 7, FIG. 8, FIG. 9, FIG. 10, FIG. 11, and FIG. 12 illustrate an example manufacturing method according to an embodiment;

FIGS. 13A and 13B illustrate an embodiment of a manufacturing apparatus for an electronic component;

FIGS. 14A and 14B illustrate an example embodiment of a manufacturing apparatus for an electronic component;

FIGS. 15A and 15B illustrate an embodiment of a manufacturing apparatus for an electronic component;

FIGS. 16A and 16B illustrate an example of a sheet;

FIGS. 17A and 17B illustrate another example of a sheet; and

FIG. 18 illustrates a manufacturing method according to an embodiment.

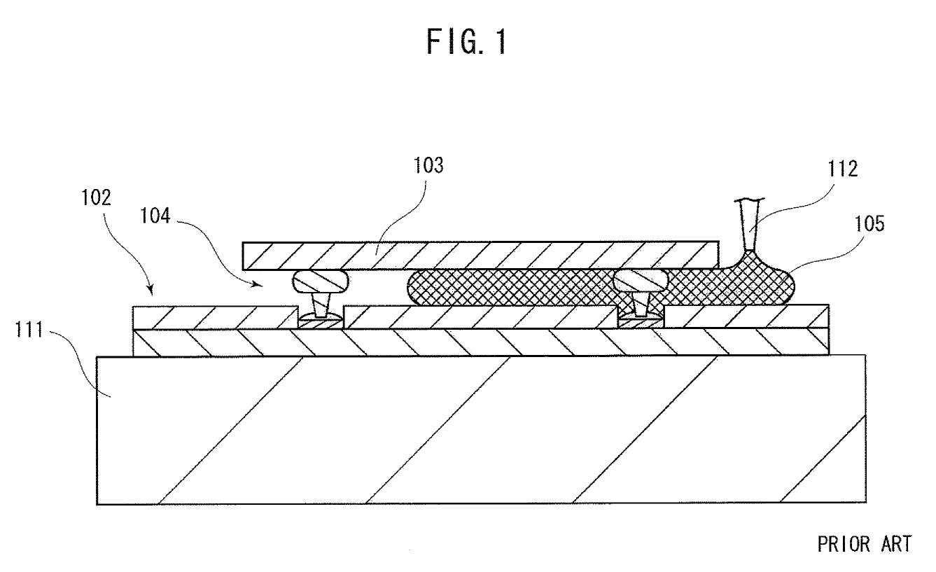

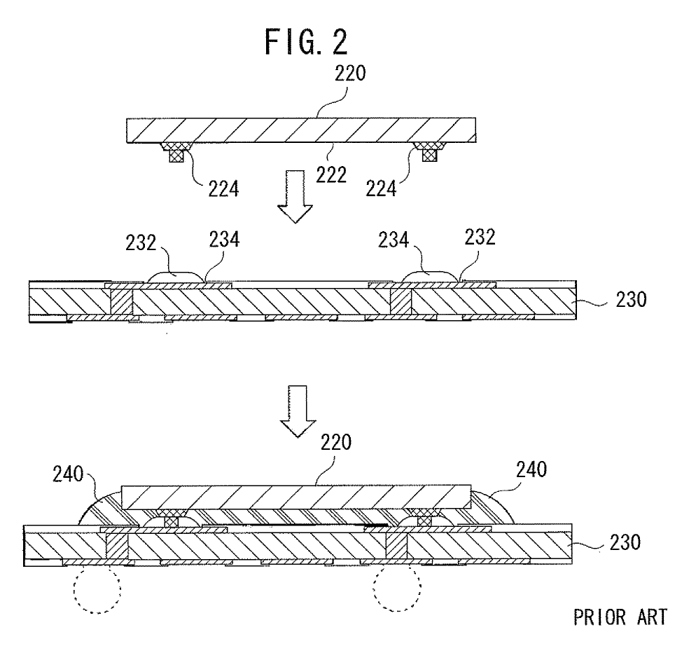

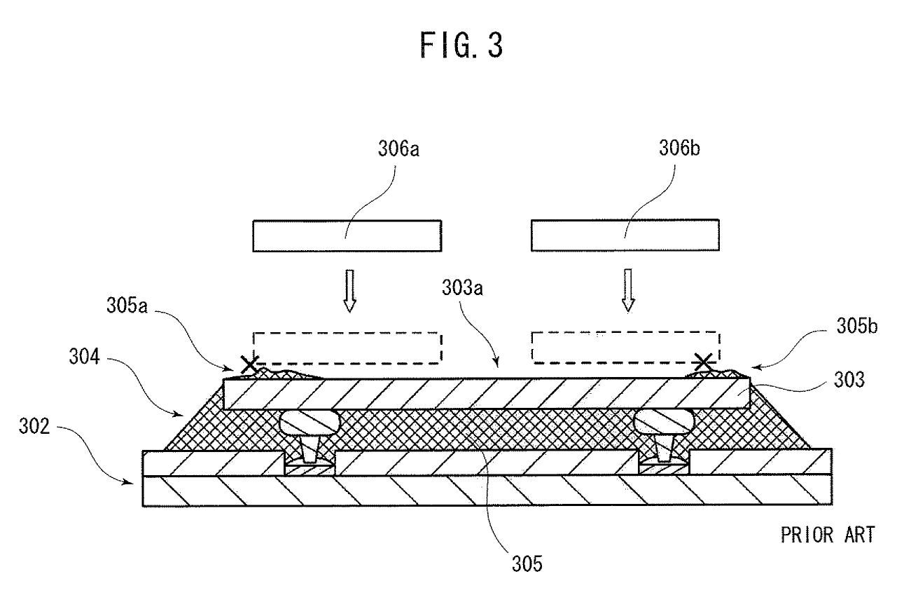

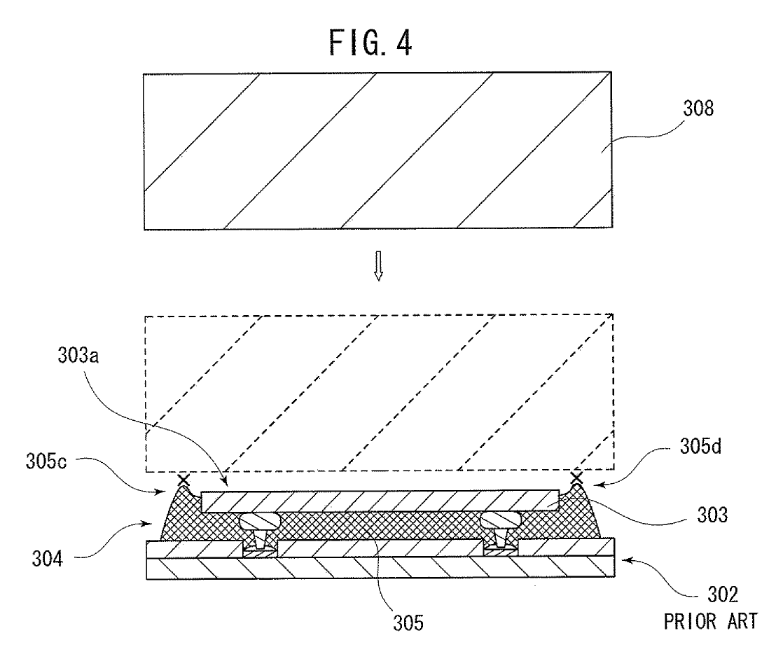

### DETAILED DESCRIPTION OF THE EMBODIMENTS

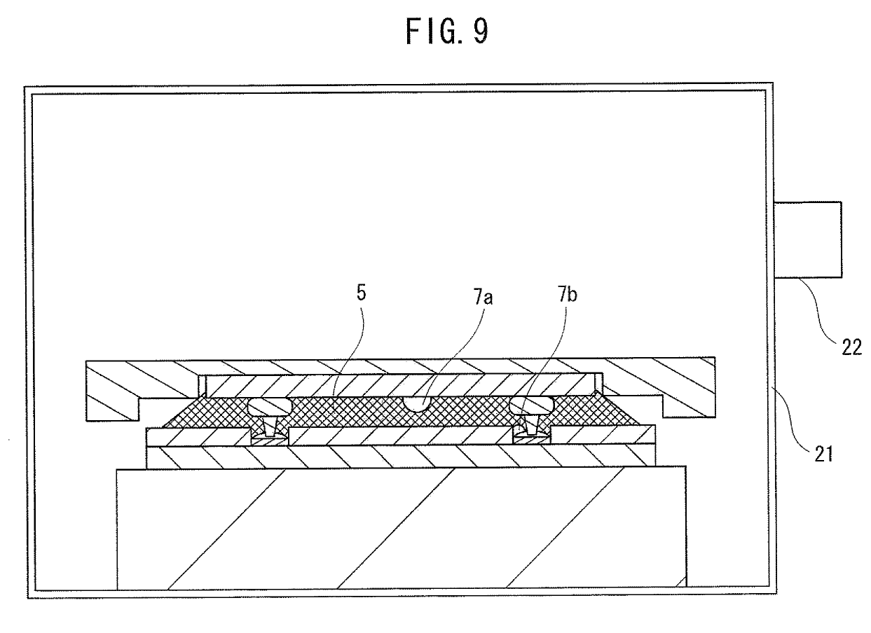

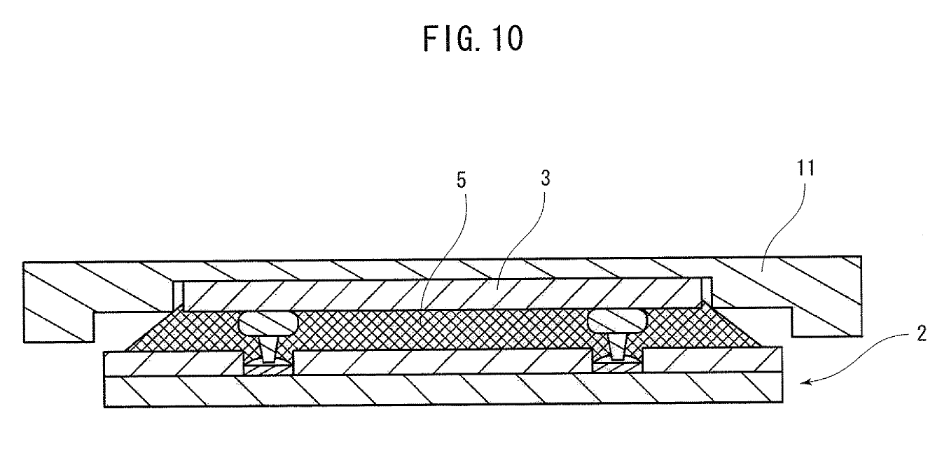

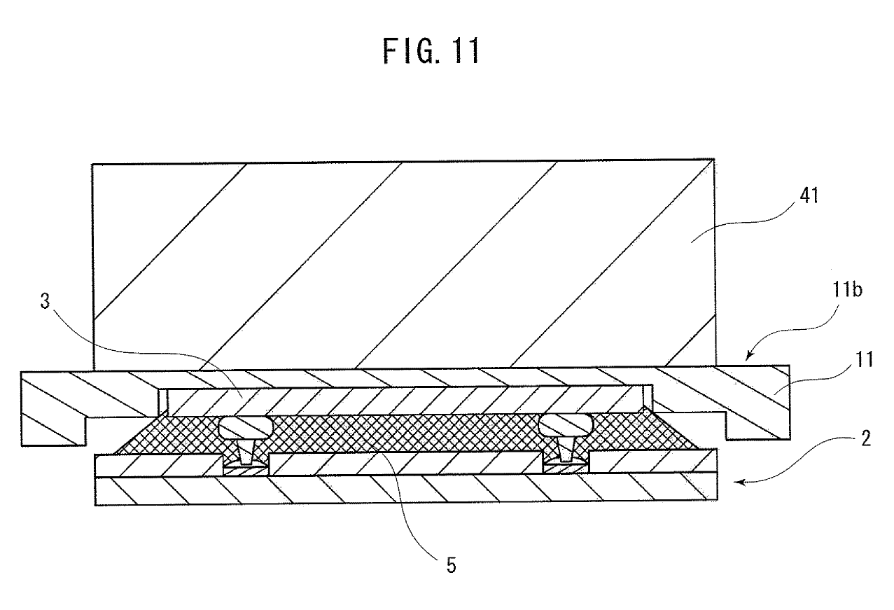

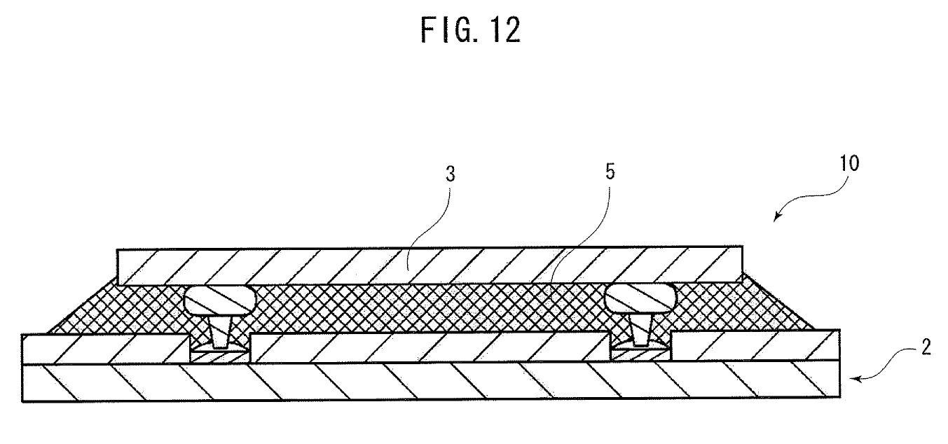

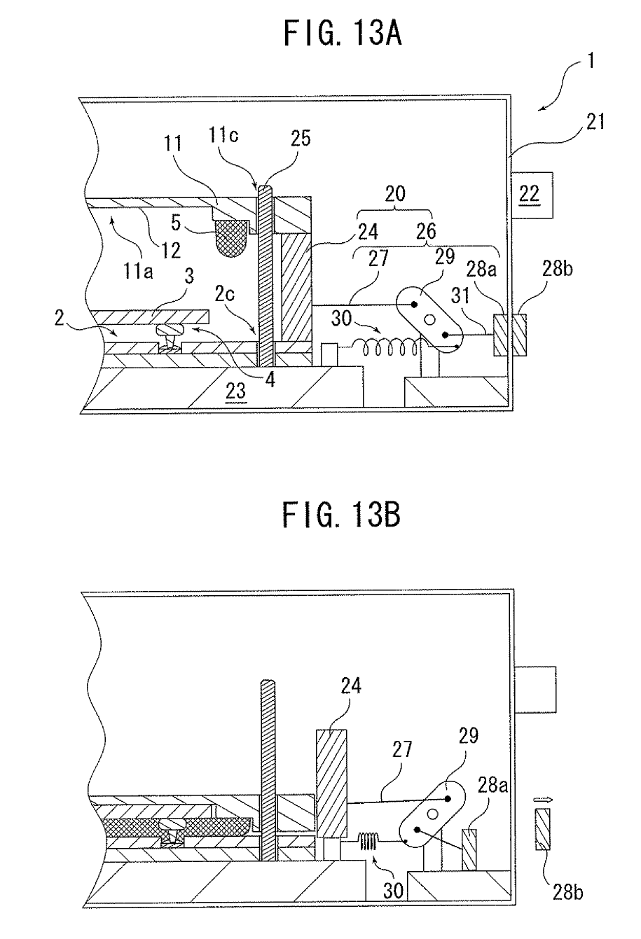

FIGS. 13A and 13B illustrate a manufacturing apparatus 1 for an electronic apparatus for manufacturing an electronic apparatus 10 by charging an adhesive 5 into a space 4 between a mounting board 2 and an electronic component 3 that is mounted on the mounting board 2. Electronic apparatuses that are manufactured in this manner include a semiconductor device in which an electronic component 3 (e.g., semiconductor chip) may be flip-chip-connected to a mounting board 2 (e.g., mounting wiring board). The distance between the mounting board 2 and the electronic component 3 in the space 4 may be about 10 to 20 μm, for example.

FIGS. 13A and 13B illustrate the manufacturing apparatus 1 may be equipped with a container 21 which may be configured so it may be reduced in pressure by a pressure reducing mechanism 22. The container 21 can accommodate a mounting board 2 that is mounted with an electronic component 3. Container 21 may include a sheet 11, a sheet lowering mechanism 20 that can hold the sheet 11 at a prescribed position and to lower the sheet 11 toward a prescribed portion of a mounting board 2 that is mounted with an electronic component 3 and to bring the former into contact with the latter, and a temperature adjustment stage 23.

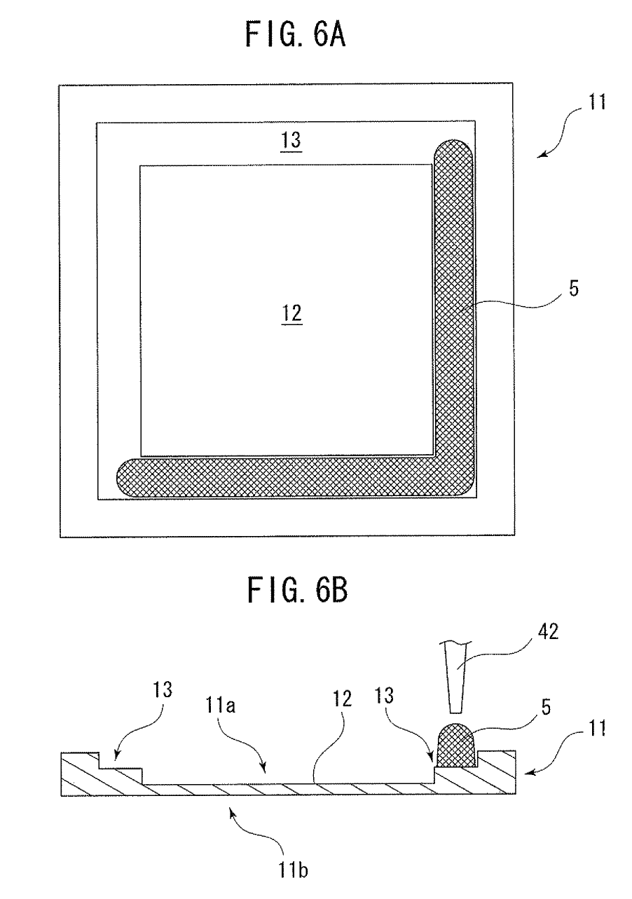

The sheet 11 makes it possible to charge a prescribed amount of adhesive 5 that is applied to one surface 11a side of the sheet 11 into a space 4 between the electronic component 3 and the mounting board 2. For example, as illustrated in FIGS. 6A and 6B, the sheet 11 has a component covering surface 12 that is a flat surface that occupies a central area of one surface 11a of the sheet 11 and may be somewhat wider than the top surface of the electronic component 3. A coating portion 13 may be formed alongside all the four sidelines of the outer circumference of the component covering surface 12 so as to have a top surface that is higher than the component covering surface 12, as illustrated in FIG. 6B). The coating portion 13 may extend alongside at least one sideline. The sheet 11 may be made of a material has a heat-resistant value higher in melting temperature than solder and to which the adhesive 5 does not stick when set. For example a conventional synthetic resin material may be used.

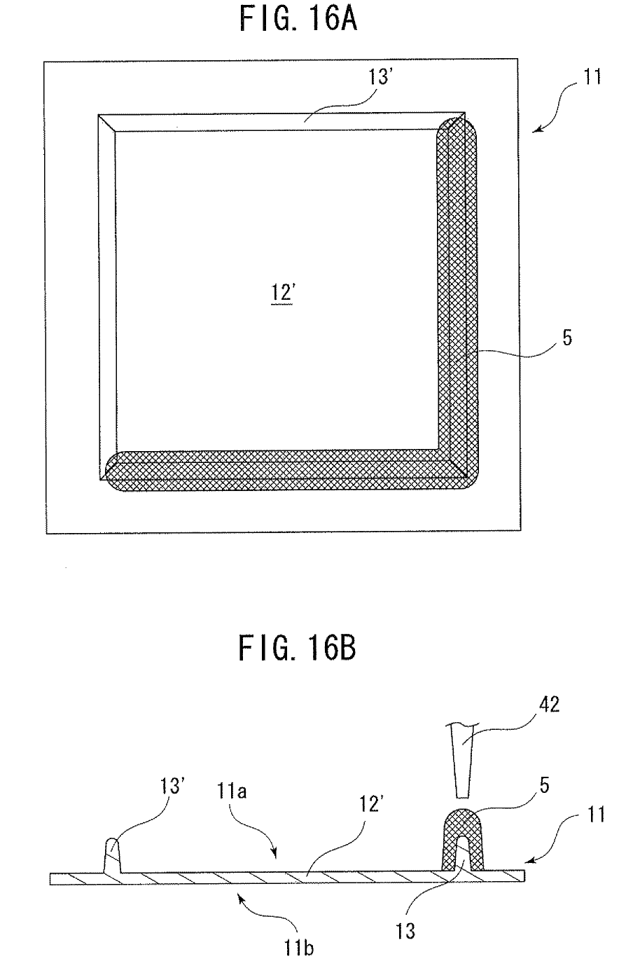

FIGS. 16A and 16B illustrate a second example of a sheet 11. A coating o portion 13′ may be formed alongside the four sidelines (it should extend alongside at least one sideline) of the outer circumference of a component covering surface 12′. The coating portion 13′ may be projection-shaped in cross section.

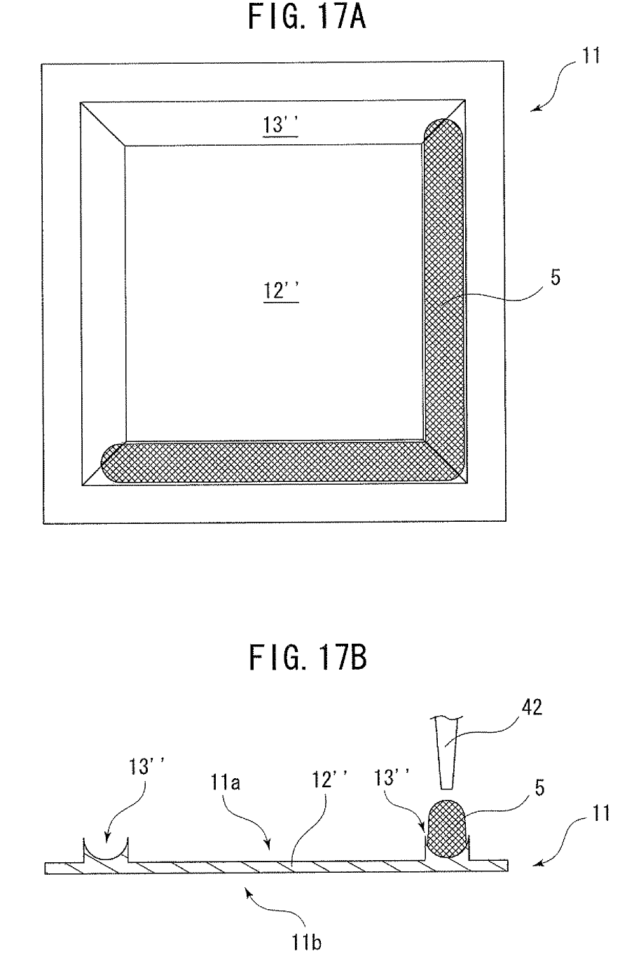

FIGS. 17A and 17B illustrate a third example of a sheet 11. A coating portion 13″ may be formed alongside the four sidelines (e.g., extend at least one sideline) of the outer circumference of a component covering surface 12″. In cross section, the coating portion 13″ may be projection-shaped and recessed at the center.

FIGS. 6A and 6B, FIGS. 16A and 16B, and FIGS. 17A and 17B each illustrate coating portion 13, 13′, or 13″ coated with an adhesive 5 supplied from a needle 42.

FIGS. 13A and 13B illustrate a sheet lowering mechanism 20 including a holding mechanism 24 and a release mechanism 26. The holding mechanism 24 may be configured so as to be able to hold the sheet 11 over the electronic component 3 and the mounting board 2 in such a manner that the one surface 11a is down and is separated from the electronic component 3 and the mounting board 2. For example, as illustrated in FIGS. 13A and 13B, the holding mechanism 24 is a rectangular member. The release mechanism 26 may be configured so as to be able to cancel the holding of the sheet 11 by the holding mechanism 24 indirectly from outside the container 21. For example, as illustrated in FIGS. 13A and 13B, the release mechanism 26 may be configured in such a manner that a first shaft 27 which is linked to the holding mechanism 24 and a second shaft 31 which is linked to one of a pair of magnetic attraction mechanisms 28a and 28b (in this example, the magnetic attraction mechanism 28a which is located inside the container 21) are linked to two end portions of a rotatable transmission member 29. When the two magnetic attraction mechanisms 28a and 28b are attracting each other, a spring member 30 produces urging force in such a direction as to rotate the transmission member 29 clockwise (see FIG. 13A).

The above-configured sheet lowering mechanism 20 acts as follows. When the magnetic attraction mechanisms 28a and 28b come not to attract each other, the urging force of the spring member 30 rotates the transmission member 29 clockwise and the holding mechanism 24 is pulled by the first shaft 27, whereby the sheet 11 is released (see FIG. 13B).

The manufacturing apparatus 1 may be equipped with a guide mechanism 25. The guide mechanism 25 serves to guide the sheet 11 so that it falls toward and comes into contact with prescribed portions of the electronic component 3 and the mounting board 2 when the sheet 11 is released. For example, FIGS. 13A and 13B, the guide mechanism 25 provides the above guide function because it is pin-shaped and penetrates through a guide hole 11c of the sheet 11 and a guide hole 2c of the mounting board 2.

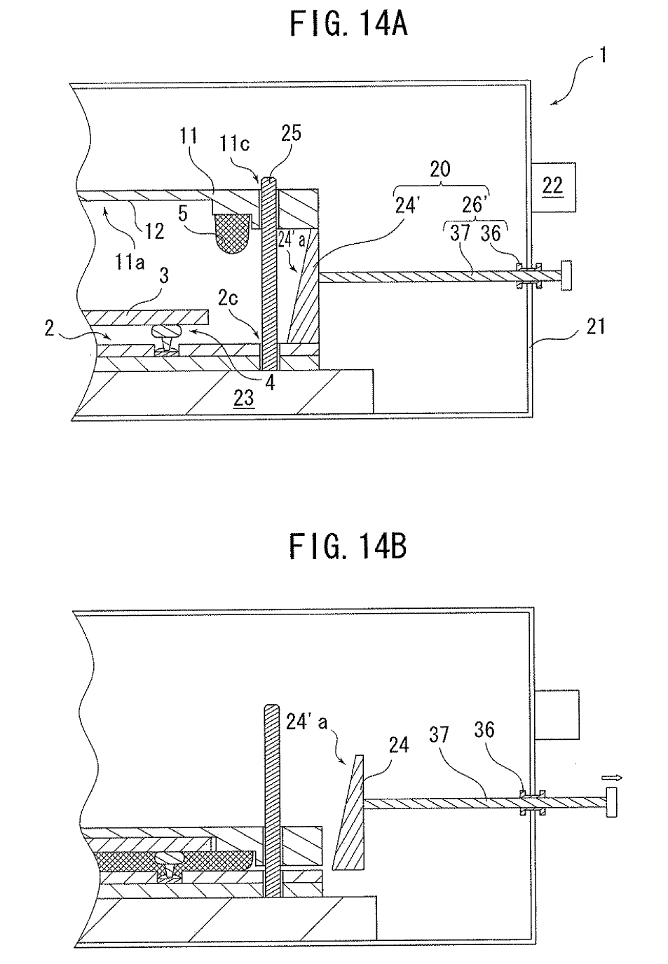

FIGS. 14A and 14B illustrate another example of the sheet lowering mechanism 20. The sheet 11 is allowed to fall while being kept in contact with an electronic-component-3-side (left side in FIGS. 14A and 14B) end surface 24′a (slant surface) of a holding mechanism 24′. As a result, the horizontal movement speed and position of the holding mechanism 24′ is controlled, which makes it possible to control the fall speed and position of the sheet 11. A release mechanism 26′ may be configured so as to be able to cancel the holding of the sheet 11 by the holding mechanism 24′ directly from outside the container 21. In the example of FIGS. 14A and 14B, the release mechanism 26′ is equipped with a shaft 37 which is linked to the holding mechanism 24′ and is supported slidably by a sliding guide 36 which is formed through a wall of the container 21. To establish a low-pressure state in the container 21, the release mechanism 26′ may be configured in such a manner that the shaft 37 is made of a metal material and the sliding guide 36 is made of a synthetic resin material and that the sliding portion is kept airtight whereas the shaft 37 is made slidable in the sliding guide 36 (see FIG. 14A).

The above-configured sheet lowering mechanism 20 may operate so as the shaft 37 is moved rightward in FIG. 14B, the holding mechanism 24′ is pulled by the shaft 37 and is moved in such a direction as to release the sheet 11. The same guide mechanism 25 may be used as previously described.

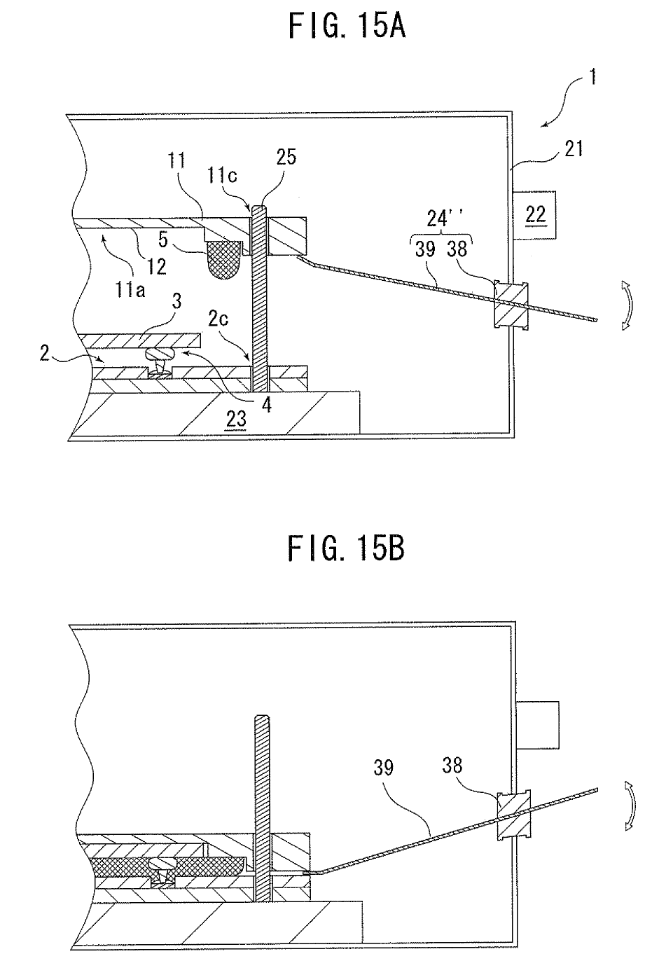

FIGS. 15A and 15B illustrate another example of the sheet lowering mechanism 20. A holding mechanism 24″ of this example may be configured in such a manner that a support shaft 39 is supported by a support member 38 which is made of an elastic member such as a rubber. The support shaft 39 operates in such a manner that its tip moves in arcs with the support member 38 as a supporting point. As a result, the support shaft 39 can be lowered while supporting the sheet 11. The release mechanism 26 or 26′ may be omitted. The same guide mechanism 25 as used in the above example may be provided.

Next, the temperature adjustment stage 23 (see FIGS. 13A and 13B etc.) of the manufacturing apparatus 1 will be described. For example, the temperature adjustment stage 23 may be configured in such a manner that the mounting board 2 can be placed on its top surface and heated to a prescribed temperature. For example, the temperature adjustment stage 23 employs a heating method using a built-in heating wire heater. The heating temperature, which depends on the material of the adhesive 5, is set at such a temperature (e.g., about 50 to 150° C.) that the viscosity of the adhesive 5 is lowered and its charging into the space 4 is thereby promoted.

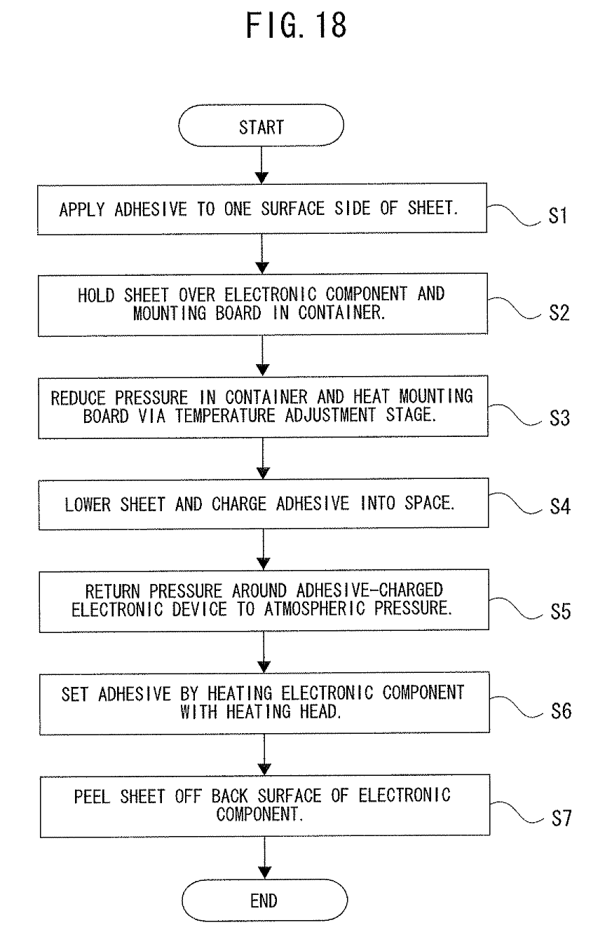

FIG. 18 illustrates a manufacturing method. For example, FIG. 12 illustrates electronic apparatus 10 may be a device which is manufactured by flip-chip-connecting an electronic component 3 (semiconductor chip) to a mounting board 2 (mounting wiring board) and charging an adhesive 5 into a space 4 between them. The electronic apparatus 10 may be manufactured by the manufacturing method charging the adhesive 5 into the space 4 of the mounting board 2 that is mounted with the electronic component 3 using, for example, the manufacturing apparatus 1 of FIGS. 13A and 13B.

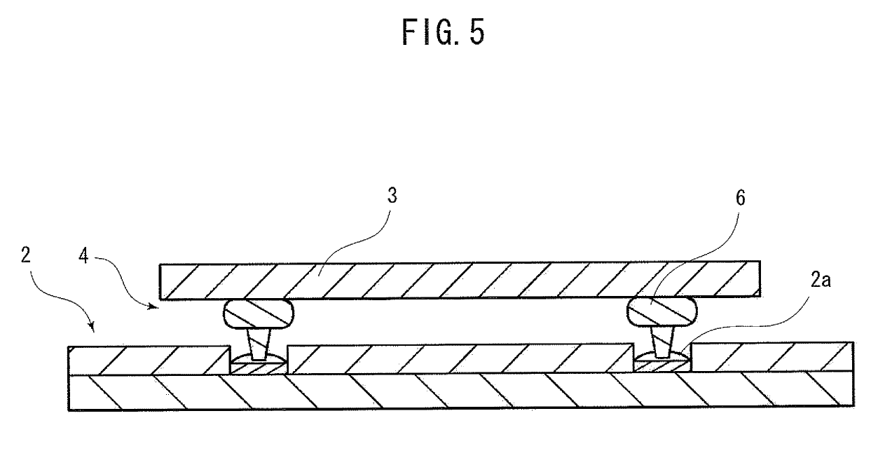

An electronic component 3 may be mounted on a mounting board 2. For example, FIG. 5 illustrates an electronic component 3 (semiconductor chip) is flip-chip-connected to a mounting board 2 (mounting wiring board). In this embodiment, the electronic component 3 is provided with plural stud bumps 6 which are connected to corresponding connection pads 2a on the mounting board 2. This mounting method can accommodate a very fine connection pitch of 50 μm or less.

FIGS. 6A and 6B illustrate an adhesive 5 for filling in the space 4 of the mounting board 2 that is mounted with the electronic component 3 is supplied from the needle 42 and the surface, on the one surface 11a side of a sheet 11, of the coating operation portion 13 is coated with a prescribed amount of adhesive 5 (operation S1). The adhesive 5 may be charged into the space 4 from one side line or two orthogonal sidelines alongside the outer circumference of the electronic component 3. In this embodiment, the adhesive 5 may be charged from two orthogonal sidelines (see FIG. 6A).

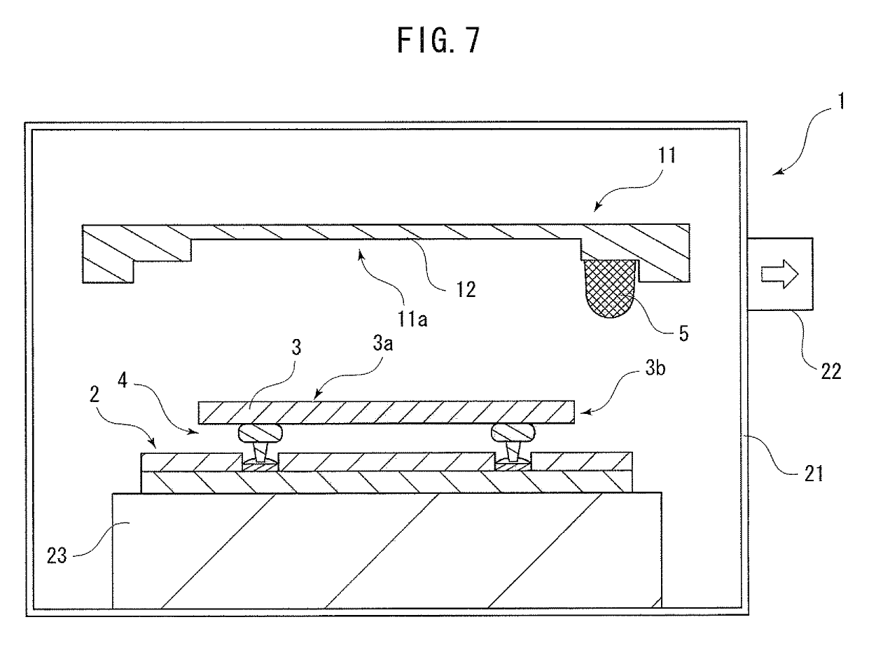

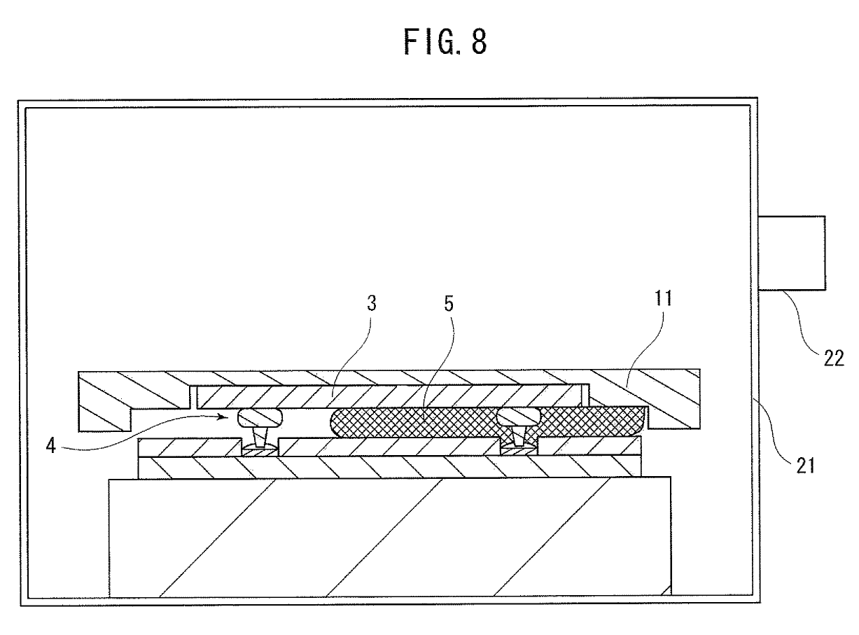

FIG. 7 illustrates mounting board 2 that is mounted with the electronic component 3 and the sheet 11 are put into the container 21. The sheet 11 may be temporarily held over the electronic component 3 and the mounting board 2 in such a manner that the one surface 11a that is coated with the adhesive 5 is down and is separated from the electronic component 3 and the mounting board 2 (operation S2).

In this state, the inside of the container 21 may be reduced in pressure by the pressure reducing mechanism 22 (operation S3). To attain intended advantageous effects the pressure in the container 21 may be reduced to about 160 Torr (about 21.3 kPa) or less.

The temperature adjustment stage 23 may be heated, whereby the temperature of the mounting board 2 that is mounted with the electronic component 3 is increased to and kept at a prescribed temperature. As mentioned above, the heating temperature, which depends on the material of the adhesive 5 and other factors, may be set so that the temperature of the mounting board 2 becomes about 50 to 150° C., for example.

FIG. 8 illustrates the sheet 11 lowered by using the sheet lowering mechanism 20 (see FIGS. 13A and 13B, for example) etc. so that the adhesive 5 that is applied to the one surface 11a side of the sheet 11 comes into contact with prescribed portions of the mounting board 2 and the electronic component 3 (operation S4). The adhesive 5 may be brought into contact with a peripheral portion 3b of the electronic component 3 and naturally charged into the space 4 by a capillary phenomenon that occurs due to the fact that the interval between the mounting board 2 and the electronic component 3 may be very small. Therefore, the contact position may be set properly according to such conditions as the height dimension of the space 4 and the amount of the adhesive 5.

The component covering surface 12 of the one surface 11a of the sheet 11 may be brought into contact with a back surface 3a of the electronic component 3 which is mounted on the mounting board 2. The back surface 3a is the surface that is opposite to the surface where the stud bumps 6 are formed.

In the operation of charging the adhesive 5 into the space 4, voids (uncharged portions 7a and 7b in FIG. 9) may occur as illustrated in FIG. 9, for example.

However, the pressure around the electronic apparatus 10 in which the space 4 is filled with the adhesive 5 is thereafter returned from the low pressure to atmospheric pressure (operation S5), an advantageous effect is obtained that the voids 7 in the adhesive 5 reduce or disappear. For example, the voids 7 that occurred under the low pressure of 160 Torr reduce in volume to about 20% (160/760) when the pressure is returned to atmospheric pressure of 760 Torr (about 101.3 kPa). In this manner, the voids 7 may be caused to disappear or reduced to such a size as not to cause a contact failure or the like. The returning to atmospheric pressure may be s done by introducing air. Alternatively, it may be done by taking the electronic apparatus 10 out of the container 21 and bringing it to a place of the next operation.

FIG. 11 illustrates adhesive 5 set by pressing a heating head 41 against the other surface 11b of the sheet 11 and heating the electronic component 3 with the heating head 41 via the sheet 11 (operation S6).

FIG. 12 illustrates the sheet 11 peeled off the back surface 3a of the electronic component 3 (operation S7).

As described above, in the manufacturing method for an electronic apparatus according to an embodiment, the sheet 11 has the component covering surface 12 that is a flat surface that occupies the central area of the one surface 11a of the sheet 11 and may be somewhat wider than the back surface 3a of the electronic component 3. The adhesive 5 is charged into the space 4 in a state that the component covering surface 12 is in contact with and covers the back surface 3a of the electronic component 3 that is mounted on the mounting board 2. This makes it possible to solve the problem of the prior art that parts of the adhesive 5 stick to the back surface 3a of the electronic component 3. This in turn makes it possible to prevent problems t when other components (e.g., memories) are stacked on the back surface 3a of the electronic component 3 unnecessary parts of the adhesive 5 render the stacking difficult to perform.

Using, as described above, the sheet 11 in charging the adhesive 5 into the space 4 makes it possible to prevent the adhesive 5 from bulging so as to be higher than the back surface 3a of the electronic component 3 around the electronic component 3. This makes it possible to solve the problem of the prior art in that the heating head 41 comes into contact with the bulges of the adhesive 5, and as a result the heating head 41 cannot be lowered to the position of the back surface 3a of the electronic component 3 to which the heating head 41 should contact and hence the electronic component 3 cannot be heated.

Furthermore, the adhesive 5 can be charged under a low-pressure environment into the space 4 between the mounting board 2 and the electronic component 3 that is mounted on the mounting board 2, voids 7, if any, can be reduced or caused to disappear. As a result, even in an electronic apparatus with a very fine wiring pitch, voids between interconnections can greatly be reduced in number and size.

According to an aspect of the invention described above, the manufacturing method for an electronic apparatus enables elimination of voids in an adhesive between a mounting board and an electronic component, prevent sticking of parts of the adhesive to the back surface of the electronic component, and prevent formation of bulges of the adhesive around the electronic component.

Further, these make it possible to lower the defective product rate of the electronic apparatus and to keep quality high.

Although the embodiments are directed to the electronic apparatus that employs flip-chip connection, the t scope of the invention can also be applied to electronic apparatuses etc. that employ wire bonding.

Further, according to an aspect of the embodiments, any combinations of the described features, functions and/or operations can be provided.

The many features and advantages of the embodiments are apparent from the detailed specification and, thus, it is intended by the appended claims to cover all such features and advantages of the embodiments that fall within the true spirit and scope thereof. Further, since numerous modifications and changes will readily occur to those skilled in the art, it is not desired to limit the inventive embodiments to the exact construction and operation illustrated and described, and accordingly all suitable modifications and equivalents may be resorted to, falling within the scope thereof.

The turn of the embodiments isn't a showing the superiority and inferiority of the invention. Although the embodiments of the present inventions have been described in detail, it should be understood that the various changes, substitutions, and alterations could be made hereto without departing from the spirit and scope of the invention.

What is claimed is:

1. A manufacturing method for an electronic apparatus, comprising:
applying to one surface of a sheet an adhesive to be charged into a space between a mounting board and an electronic component mounted on the mounting board;
bringing the one surface of the sheet into contact with a back surface of the electronic component mounted on the mounting board and charging the adhesive into the space by bringing the adhesive into contact with a peripheral portion of the electronic component under a low pressure; and
pressing a heating head against the other surface of the sheet and heating the sheet with the heating head via the sheet to set the adhesive under atmospheric pressure, in a state that the sheet is in contact with the electronic component.

2. The manufacturing method according to claim 1, wherein a value of a heat-resistance of the sheet is higher in melting temperature than solder and has such a characteristic that the adhesive does not stick to it when set, and
wherein the sheet comprises a component covering surface which is a flat surface that is part of the one surface and is somewhat wider than the back surface of the electronic component and a coating portion that is formed alongside at least one sideline of an outer circumference of the component covering surface so as to have a top surface that is higher than the component covering surface.

3. The manufacturing method according to claim 1, wherein the low pressure is 160 Torr or less.

4. The manufacturing method according to claim 1, wherein the adhesive is charged while at least one of the mounting board and the electronic component is heated to about 50 to 150° C.

5. A manufacturing apparatus for an electronic apparatus, comprising:
a container capable of being reduced in inside pressure and accommodating a mounting board that is mounted with an electronic component;
a sheet provided in the container and to be used in charging an adhesive that is applied to one surface of the sheet into a space between the electronic component and the mounting board; and
a sheet lowering mechanism provided in the container, capable of holding the sheet over the electronic component and the mounting board in such a manner that the one surface is down and is separated from the electronic component and the mounting board, the sheet lowering mechanism serving to lower the sheet toward prescribed portions of the electronic component and the mounting board and to thereby bring the sheet into contact with the electronic component and the mounting board.

6. The manufacturing apparatus according to claim 5, further comprising a temperature adjustment stage capable of adjusting temperature of the mounting board.

7. A sheet for manufacturing an electronic apparatus, comprising:
a surface to be coated with an adhesive to be charged into a space between a mounting board and an electronic component mounted on the mounting board;
a component covering surface which is a flat surface that is part of the one surface and is somewhat wider than a back surface of the electronic component; and
a coating portion that is formed alongside at least one sideline of an outer circumference of the component covering surface so as to have a top surface that is higher than the component covering surface,
wherein a value of a heat-resistance of the sheet is higher in melting temperature than solder and has such a characteristic that the adhesive does not stick to it when set.
